(19) United States
(12) Patent Application Publication
(10) Pub. No.: US 2019/0013412 A1
(43) Pub. Date: Jan. 10, 2019

(54) THIN FILM TRANSISTOR, MANUFACTURING METHOD THEREOF AND DISPLAY

(71) Applicant: Shenzhen China Star Optoelectronics Semiconductor Display Technology Co., Ltd., Shenzhen, Guangdong (CN)

(72) Inventor: Huafei XIE, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/557,452

(22) PCT Filed: Aug. 18, 2017
(86) PCT No.: PCT/CN2017/097967

§ 371 Date: Sep. 11, 2017

(30) Foreign Application Priority Data
Jul. 4, 2017 (CN) 201710536953.3

(51) Int. Cl. H01L 29/786; H01L 21/02; H01L 29/12; H01L 21/285; H01L 21/768; H01L 29/66; H01L 27/12

(52) U.S. Cl. CPC H01L 29/78696; H01L 27/127; H01L 21/02628; H01L 21/02532; H01L 29/127; H01L 29/78648; H01L 21/2855; H01L 21/02274; H01L 21/02164; H01L 21/76802; H01L 21/76877; H01L 29/66742; H01L 29/78651; H01L 27/1222; H01L 29/78618

(57) ABSTRACT

Provided is a thin film transistor, a manufacturing method thereof and a display. The method comprises steps of: forming a source pattern layer and a drain pattern layer above a substrate, wherein a channel area is formed between the source pattern layer and the drain pattern layer; forming an active layer in the channel area with a solution containing silicon quantum dots. With this method, the active layer of the thin film transistor is manufactured by spin coating with silicon quantum dots as material in the present invention. The manufacturing process is simple and the production cost is reduced to enrich the preparation materials of thin film transistor for promoting the mobility of the silicon-based thin film transistor, which is beneficial to improve the electrical uniformity of large area silicon-based thin film transistors.

### FIELD OF THE INVENTION

The present invention relates to a display field, and more particularly to a thin film transistor, a manufacturing method thereof and a display.

### BACKGROUND OF THE INVENTION

Since the colloidal quantum dots are found to have quantum size effect, a great application in the electronic and optoelectronics field has been obtained in the film formation. Based on the advantages of adjustable size gap, small exciton binding energy, high electrification and photoluminescence efficiency and low cost solution process, the quantum dots have been successfully applied in the thin film optoelectronic devices, such as solar cells and light emitting diodes. However, the charge transport performance and application of the quantum dots in the thin film transistor are rarely reported and far behind the commercial silicon transistors and the organic field effect transistors.

The effective overlap and the coincidence of the quantum confinement electrons or the hole wave function by the close packing of the semiconductor quantum dots can form a new type of artificial thin film, which doe not only retain the unique performance tunability of quantum dots material but also possesses a higher carrier mobility and a higher electrical conductivity. Compared with the silicon type transistor, the transistor, in which the quantum dots are used as the carrier transporting layer possesses the advantages of the solution preparation process, simple, low cost, good weight and good flexibility. Particularly as regarding of the silicon quantum dots, the silicon quantum dots are silicon monocrystals with a lattice distribution in three dimensions of less than 100 nm and a single silicon surface. The strong quantum confinement of carriers (such as electrons, holes and excitons) in the silicon quantum dot structure makes the electrical and optical properties thereof significantly changed and can be widely used in micro nano electronic devices, optoelectronic devices and thermoelectric devices.

### SUMMARY OF THE INVENTION

An objective of the present invention is to provide a thin film transistor, a manufacturing method thereof and a display for solving the problem of how to use silicon quantum dots to prepare thin film transistors.

For solving the aforesaid technical issue, another technical solution employed by the present invention is: providing a manufacturing method of a thin film transistor. The method comprises: sequentially forming a bottom gate pattern layer and a bottom gate insulating layer covering the bottom gate pattern layer on a substrate; forming a source pattern layer and a drain pattern layer above the substrate, wherein a channel area is formed between the source pattern layer and the drain pattern layer; forming an active layer in the channel area with a solution containing silicon quantum dots; wherein the step of forming the active layer in the channel area with the solution containing silicon quantum dots comprises: forming a silicon quantum dots layer in the channel area with the solution containing silicon quantum dots by spin coating; evaporating the silicon quantum dots layer in vacuum at a low temperature to form a silicon quantum dots active layer.

For solving the aforesaid technical issue, another technical solution employed by the present invention is: providing a thin film transistor. The thin film transistor comprises: a source pattern layer and a drain pattern layer above a substrate, wherein the source pattern layer and the drain pattern layer are spaced and a channel area is formed between the source pattern layer and the drain pattern layer; an active layer, which is in the channel area and comprises silicon quantum dots.

For solving the aforesaid technical issue, another technical solution employed by the present invention is: providing a display. The display comprises the aforesaid thin film transistor.

The benefits of the present invention are: different from prior arts, the method of the present invention comprises steps of forming a source pattern layer and a drain pattern layer above a substrate, wherein a channel area is formed between the source pattern layer and the drain pattern layer; and forming an active layer in the channel area with a solution containing silicon quantum dots. The active layer of the thin film transistor is manufactured with silicon quantum dots as material to enrich the preparation materials of thin film transistor for promoting the mobility of the silicon-based thin film transistor, which is beneficial to improve the electrical uniformity of large area silicon-based thin film transistors.

### BRIEF DESCRIPTION OF THE DRAWINGS

FIG. 1 is a flowchart diagram of the first embodiment according to a manufacturing method of a thin film transistor provided by the present invention;

FIG. 2 is a structure diagram of the first embodiment according to a thin film transistor provided by the present invention;

FIG. 3 is a specific flowchart diagram of Step S13 in FIG. 1;

FIG. 4 is a flowchart diagram of the second embodiment according to a manufacturing method of a thin film transistor provided by the present invention;

FIG. 5 is a structure diagram of the second embodiment according to a thin film transistor provided by the present invention;

FIG. 6 is a flowchart diagram of the third embodiment according to a manufacturing method of a thin film transistor provided by the present invention;

FIG. 7 is a structure diagram of the third embodiment according to a thin film transistor provided by the present invention.

### DETAILED DESCRIPTION OF PREFERRED EMBODIMENTS

In order to enable persons skilled in the art to better understand the technical solution of the present invention, the thin film transistor, the manufacturing method thereof and the display provided by the present invention are described in detail with reference to the accompanying drawings and specific embodiments as follows.

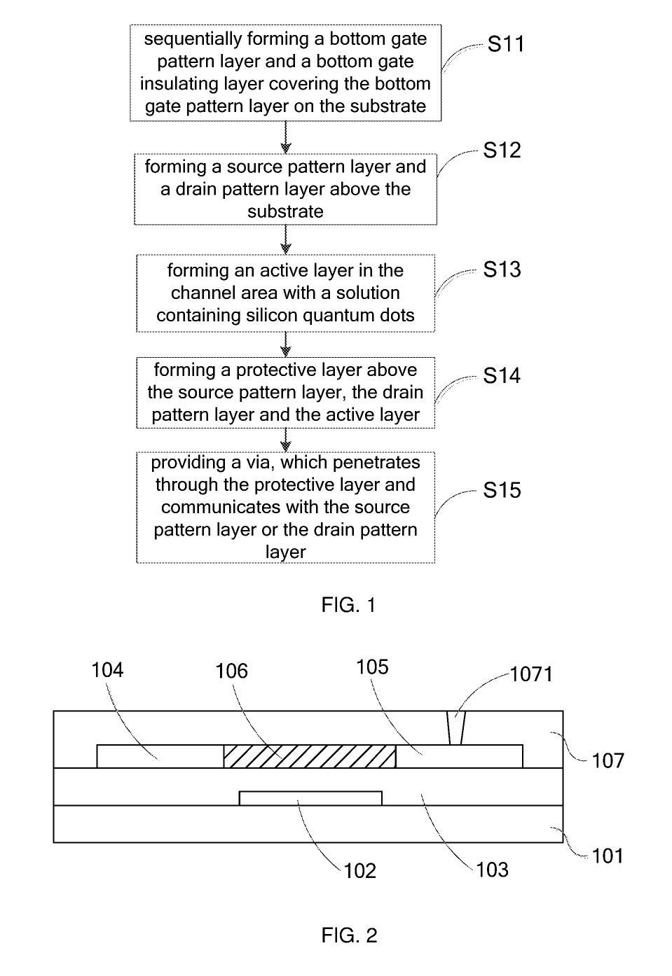

Please refer to FIG. 1 and FIG. 2. The first embodiment of a manufacturing method of a thin film transistor provided by the present invention comprises:

S11: sequentially forming a bottom gate pattern layer 102 and a bottom gate insulating layer 103 covering the bottom gate pattern layer 102 on the substrate 101; specifically, a metal film may be deposited on the substrate 101 by physical vapor deposition after the substrate 101 is cleaned and the bottom gate pattern layer 102 is formed by photolithography process of coating, exposure, development and stripping; furthermore, an insulating material layer of a certain thickness can be deposited on the substrate 101 by physical vapor deposition or plasma vapor deposition to form the bottom gate insulating layer 103.

Optionally, the substrate 101 can be but not limited to a quartz substrate, a glass substrate, or a silicon substrate; a material of the metal material layer is a conductive metal including but not limited to aluminum, silver, copper, ITO, gold or titanium; the insulating material can be but not limited to an insulating material of silica, alumina, silicon nitride or ionic gels; a thickness of the bottom gate insulating layer 103 is 200 nm.

Step S12: forming a source pattern layer 104 and a drain pattern layer 105 above the substrate 101; specifically, the substrate 101 after the aforesaid Step S11 is accomplished is soaked in a solution of acetone, methanol and isopropanol and dried at a certain temperature and then, is baked at a certain temperature and placed in a steaming machine. Then, a metal material layer is deposited on the bottom gate insulating layer 103 by thermal deposition with a mask to form the source pattern layer 104 and the drain pattern layer 105.

Optionally, a material of the metal material layer is a conductive metal including but not limited to aluminum, silver, copper, ITO, gold or titanium; a thickness of the formed metal material layer is 100 nm.

A channel area (not shown in figure) is formed between the source pattern layer 104 and the drain pattern layer 105.

Step S13: forming an active layer 106 in the channel area with a solution containing silicon quantum dots; here, the mechanical polishing is illustrated for explanation. First, preliminary preparation is performed: a large piece of silicon is cut into small pieces of silicon having a cross-sectional size of 1.2 cm×1.2 cm to be soaked for two hours with a mixed solution of concentrated sulfuric acid and hydrogen peroxide and finally, the small pieces of silicon preserved in ethanol after washing with ionized water; then, mechanical grinding is performed: the preserved small pieces of silicon were immersed in a 40% concentration of hydrofluoric acid solution for 1 minute and rinsed three times with ionized water and then, two small pieces of silicon are placed in a zirconia grinding can in an argon glove box and sealed and then, the sealed zirconia grinding can is placed in a high-energy nano-impact grinding arm for high-speed grinding of high-energy nano-grinding machine circulating water and then, after grinding in four hours, the grinding can is opened in the glove box of the argon atmosphere to withdraw the initial sample of silicon powder; at last, the solution formation is performed: the obtained sample is dispersed in n-hexane and then, is filtered with a 100 nm filter to obtain a silicon quantum dot solution of a certain concentration.

A concentration of silicon quantum dots in the silicon quantum dots solution is 2.5 mg/ml.

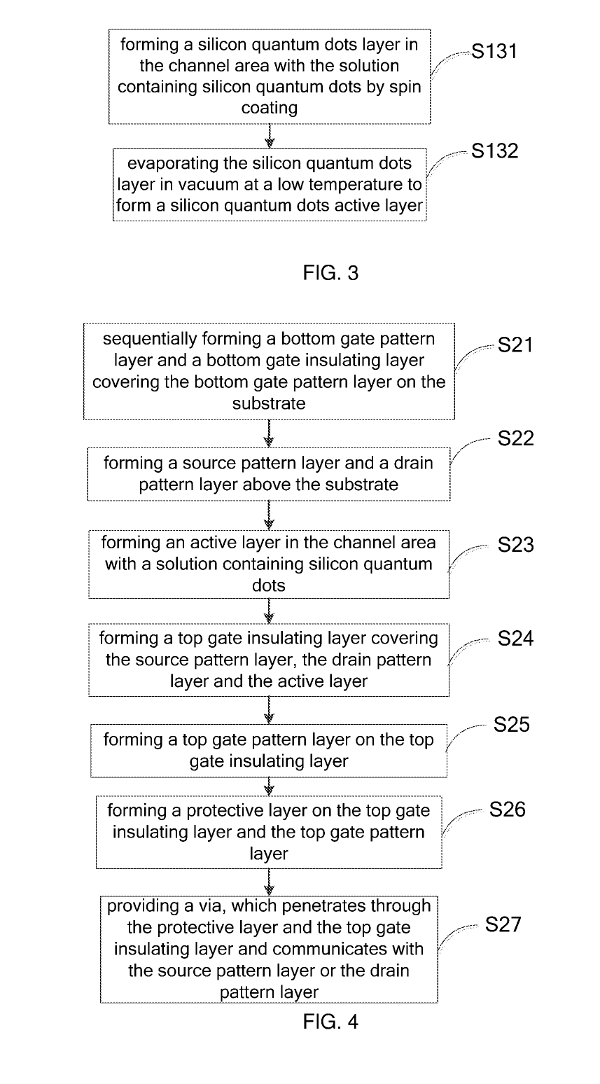

Please refer to FIG. 3, Step S13 specifically comprises:

Step S131: forming a silicon quantum dots layer in the channel area with the solution containing silicon quantum dots by spin coating; specifically, the aforesaid solution comprising the silicon quantum dots may be dropped and added in the channel area in a glove box containing a high-purity inert gas and the silicon quantum dots layer of a certain thickness may be formed in a certain period by spin coating.

Optionally, the inert gas is nitrogen, the number of revolutions of the spin coating is 3000 rpm and the spin coating time is 30 seconds.

Step S132: evaporating the silicon quantum dots layer in vacuum at a low temperature to form a silicon quantum dots active layer.

Specifically, the silicon quantum dots layer is vacuum baked, such as the silicon quantum dot film is baked in a vacuum environment at 80 Celsius degrees and the active layer 106 can be obtained after about 12 hours.

Step S14: forming a protective layer 107 above the source pattern layer 104, the drain pattern layer 105 and the active layer 106; optionally, silicon oxide may be on the bottom gate insulating layer 103, the source pattern layer 104, the drain pattern layer 105 and the active layer 106 by chemical vapor deposition to form the protective layer 107 covering the source pattern layer 104, the drain pattern layer 105 and the active layer 106.

Step S15: providing a via 1071, which penetrates through the protective layer 107 and communicates with the source pattern layer 104 or the drain pattern layer 105; specifically, the via 1071 communicating with the source pattern layer 104 or the drain pattern layer 105 is etched in the protective layer 107 by a photolithography process of photoresist coating, exposure, development and stripping. The via communicating with the drain pattern layer 105 is illustrated in the figure of this embodiment.

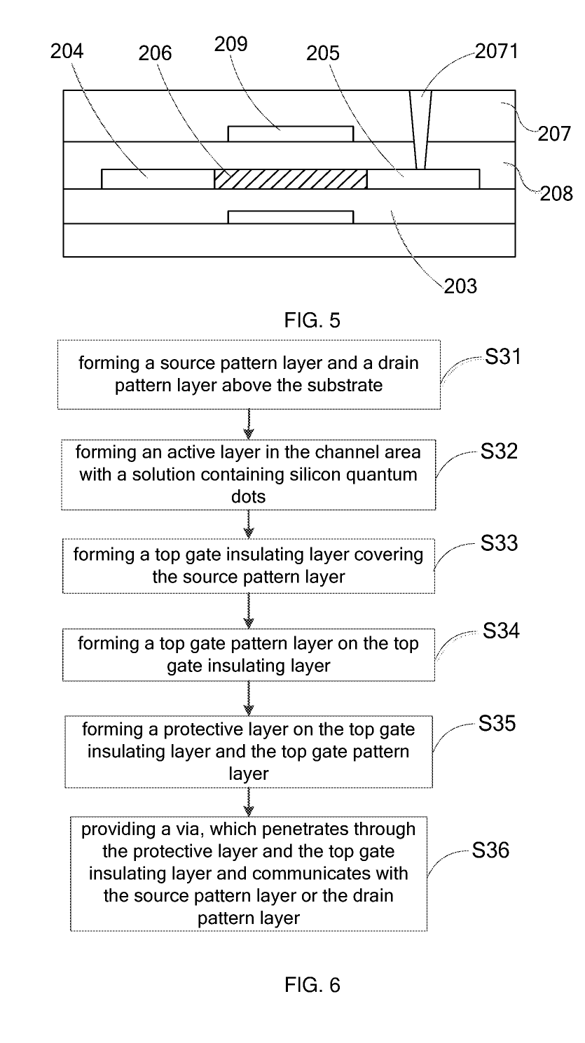

Please refer to FIG. 4 and FIG. 5. Steps S21, S22 and S23 in the second embodiment according to the manufacturing method of the thin film transistor provided by the present invention are the same as Steps S11, S12 and S13 in the foregoing first embodiment and repeated description is omitted here. This embodiment further comprises steps of:

Step S24: forming a top gate insulating layer 208 covering the source pattern layer 204, the drain pattern layer 205 and the active layer 206;

specifically, an insulating material layer of a certain thickness can be deposited on bottom gate insulating layer 203, the source pattern layer 204, the drain pattern layer 205 and the active layer 206 by physical vapor deposition or plasma vapor deposition to form the top gate insulating layer 208.

optionally, the insulation material can be an insulation material of silica, alumina, silicon nitride or ionic gels but not limited thereto. A thickness of the formed top gate insulating layer 208 is 300 nm.

Step 25: forming a top gate pattern layer 209 on the top gate insulating layer 208; specifically, a metal film may be deposited on the top gate insulating layer 208 by physical vapor deposition and the top gate pattern layer 209 is formed by photolithography process of exposure, development, etching and stripping.

Optionally, a material of the metal material layer is a conductive metal including but not limited to aluminum, silver, copper, ITO, gold or titanium.

Step 26: forming a protective layer 207 on the top gate insulating layer 208 and the top gate pattern layer 209.

Specifically, silicon oxide is deposited on the top gate insulating layer 208 by chemical vapor deposition to form the protective layer 207 covering the top gate insulating layer 208 and the top gate pattern layer 209.

Step S27: providing a via 2071, which penetrates through the protective layer 207 and the top gate insulating layer 208 and communicates with the source pattern layer 204 or the drain pattern layer 205.

Specifically, the via 2071 communicating with the source pattern layer 204 or the drain pattern layer 205 is etched in the protective layer 207 and the top gate insulating layer 208 by a photolithography process of photoresist coating, exposure, development and stripping.

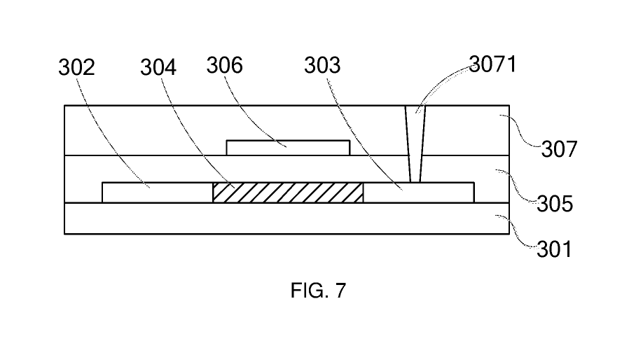

Please refer to FIG. 6 and FIG. 7. The third embodiment according to the manufacturing method of the thin film transistor provided by the present invention comprises:

Step S31: forming a source pattern layer 302 and a drain pattern layer 303 above the substrate 301; wherein the source pattern layer 302 and a drain pattern layer 303 in this embodiment are formed on the substrate 301 and the formation method is the same as Step S12 in the aforesaid first embodiment. The repeated description is omitted here.

Step S32: forming an active layer 304 in the channel area (not shown in figure) with a solution containing silicon quantum dots;

Step S32 is the same as Step S13 in the foregoing first embodiment and the repeated description is omitted here.

Step S33: forming a top gate insulating layer 305 covering the source pattern layer 302, the drain pattern layer 303 and the active layer 304; specifically, an insulating material layer of a certain thickness can be deposited on the substrate 301 by physical vapor deposition or plasma vapor deposition to form the top gate insulating layer 305; optionally, the insulation material can be an insulation material of silica, alumina, silicon nitride or ionic gels but not limited thereto.

Step 34: forming a top gate pattern layer 306 on the top gate insulating layer 305; specifically, a metal film may be deposited on the top gate insulating layer 305 by physical vapor deposition and the top gate pattern layer 306 is formed by photolithography process of exposure, development, etching and stripping.

Optionally, a material of the metal material layer is a conductive metal including but not limited to aluminum, silver, copper, ITO, gold or titanium.

Step 35: forming a protective layer 307 on the top gate insulating layer 305 and the top gate pattern layer 306; optionally, silicon oxide is deposited on the top gate insulating layer 305 by chemical vapor deposition to form the protective layer 307 covering the top gate insulating layer 305 and the top gate pattern layer 306.

Step S36: providing a via 3071, which penetrates through the protective layer 307 and the top gate insulating layer 305 and communicates with the source pattern layer 302 or the drain pattern layer 303.

Specifically, the via 3071 communicating with the source pattern layer 302 or the drain pattern layer 303 is etched in the protective layer 307 and the top gate insulating layer 305 by a photolithography process of photoresist coating, exposure, development and stripping.

Please refer to FIG. 2. The first embodiment according to the thin film transistor provided by the present invention comprises a bottom gate pattern layer 102, a bottom gate insulating layer 103, a source pattern layer 104, a drain pattern layer 105, an active layer 106 and a protective layer 107 above a substrate 101.

The bottom gate pattern layer 102 and the bottom gate insulating layer 103 are sequentially formed on the substrate 101 and the bottom gate insulating layer 103 covers the bottom gate pattern layer 102; the source pattern layer 104 and the drain pattern layer 105 are formed on the bottom gate insulating layer 103 with a channel area formed therebetween and the active layer 106 is in the channel area and comprises silicon quantum dots; the protective layer 107 covers the source pattern layer 104, the drain pattern layer 105 and the active layer 106 and the protective layer 107 has a via 1071 penetrating the protective layer 107 and communicating with the source pattern layer 104 or the drain pattern layer 105.

The structure of each layer in this embodiment is prepared by the corresponding steps in the foregoing first embodiment according to the manufacturing method of the thin film transistor and the repeated description is omitted here.

Please refer to FIG. 5. The second embodiment according to the thin film transistor provided by the present invention further comprises a top gate insulating layer 208 and a top gate pattern layer 209. The other structures in this embodiment are the same as those of the foregoing first embodiment of the field effect transistor and the repeated description is omitted here.

The top gate insulating layer 208 is formed on the bottom gate insulating layer 203 and covers the source pattern layer 204, the drain pattern layer 205 and the active layer 206. The top gate pattern layer 209 is formed on the top gate insulating layer 208.

The structure of each layer in this embodiment is prepared by the corresponding steps in the foregoing second embodiment according to the manufacturing method of the thin film transistor and the repeated description is omitted here.

Please refer to FIG. 7. The third embodiment according to the thin film transistor provided by the present invention comprises a source pattern layer 302 and a drain pattern layer 303, an active layer 304, a top gate insulating layer 305 covering the source pattern layer 302, the drain pattern layer 303 and the active layer 304, a top gate pattern layer formed on the top gate insulating layer 305, a protective layer formed above the source pattern layer 302, the drain pattern layer 303 and the active layer 304.

The structure of each layer in this embodiment is prepared by the corresponding steps in the foregoing third embodiment according to the manufacturing method of the thin film transistor and the repeated description is omitted here.

The present invention further provides a display, comprising the thin film transistor in any of the aforesaid embodiments.

Different from prior arts, the present invention comprises steps of forming a source pattern layer and a drain pattern layer above a substrate, wherein a channel area is formed between the source pattern layer and the drain pattern layer; and forming an active layer in the channel area with a solution containing silicon quantum dots. The active layer of the thin film transistor is manufactured by spin coating with silicon quantum dots as material. The manufacturing process is simple and the production cost is reduced to enrich the preparation materials of thin film transistor for promoting the mobility of the silicon-based thin film transistor, which is beneficial to improve the electrical uniformity of large area silicon-based thin film transistors.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacturing method of a thin film transistor, comprising steps of:
sequentially forming a bottom gate pattern layer and a bottom gate insulating layer covering the bottom gate pattern layer on a substrate;
forming a source pattern layer and a drain pattern layer above the substrate, wherein a channel area is formed between the source pattern layer and the drain pattern layer;
forming an active layer in the channel area with a solution containing silicon quantum dots;
wherein the step of forming the active layer in the channel area with the solution containing silicon quantum dots comprises:
forming a silicon quantum dots layer in the channel area with the solution containing silicon quantum dots by spin coating;
evaporating the silicon quantum dots layer in vacuum at a low temperature to form a silicon quantum dots active layer.

2. The method according to claim 1, wherein the method further comprise:
forming a top gate insulating layer covering the source pattern layer, the drain pattern layer and the active layer;
forming a top gate pattern layer on the top gate insulating layer.

3. The method according to claim 2, wherein the method further comprise:
forming a protective layer above the source pattern layer, the drain pattern layer and the active layer;
providing a via, which penetrates through the protective layer and communicates with the source pattern layer or the drain pattern layer.

4. The method according to claim 1, wherein the step of sequentially forming the bottom gate pattern layer and the bottom gate insulating layer covering the bottom gate pattern layer on the substrate comprises:
depositing a metal film on the substrate by physical vapor deposition and forming the bottom gate pattern layer by photolithography process;
depositing an insulating material layer on the substrate by plasma vapor deposition to form the bottom gate insulating layer.

5. The method according to claim 3, wherein the step of forming the protective layer above the source pattern layer, the drain pattern layer and the active layer comprises:
depositing silicon oxide on the bottom gate insulating layer, the source pattern layer, the drain pattern layer and the active layer by chemical vapor deposition to form the protective layer.

6. The method according to claim 3, wherein the step of forming the protective layer above the source pattern layer, the drain pattern layer and the active layer comprises:
depositing silicon oxide on the top gate insulating layer by chemical vapor deposition to form the protective layer top gate insulating layer and the top gate pattern layer.

7. The method according to claim 6, wherein the step of providing the via, which penetrates through the protective layer and communicates with the source pattern layer or the drain pattern layer comprises:
etching the via, which communicates with the source pattern layer or the drain pattern layer in the protective layer and the top gate insulating layer by photolithography process.

8. The method according to claim 1, wherein a concentration of silicon quantum dots in the solution containing silicon quantum dots is 2.5 mg/ml.

9. The method according to claim 1, wherein a number of revolutions of the spin coating is 3000 rpm and a spin coating time is 30 seconds.

10. A thin film transistor, comprising:
a source pattern layer and a drain pattern layer above a substrate, wherein the source pattern layer and the drain pattern layer are spaced and a channel area is formed between the source pattern layer and the drain pattern layer;
an active layer, which is in the channel area and comprises silicon quantum dots.

11. The thin film transistor according to claim 10, wherein the thin film transistor further comprises a bottom gate pattern layer and a bottom gate insulating layer covering the bottom gate pattern layer, which are sequentially formed on the substrate and the source pattern layer and the drain pattern layer are formed on the bottom gate insulating layer.

12. The thin film transistor according to claim 10, wherein the thin film transistor further comprises a top gate insulating layer and a top gate pattern layer, the top gate insulating layer covers the source pattern layer, the drain pattern layer and the active layer, the top gate pattern layer is formed on the top gate insulating layer.

13. The thin film transistor according to claim 12, wherein the thin film transistor further comprises a protective layer, the protective layer is formed above the source pattern layer, the drain pattern layer and the active layer, a via penetrating the protective layer and communicating with the source pattern layer or the drain pattern layer is provided.

14. A display, comprising the thin film transistor according to claim 10.
